(19) United States
(12) Patent Application Publication
(10) Pub. No.: US 2025/0328701 A1
(43) Pub. Date: Oct. 23, 2025

(54) GENERATING SIMULATION ENVIRONMENTS FOR TESTING AUTONOMOUS VEHICLE BEHAVIOUR

(71) Applicant: Five AI Limited, Cambridge (GB)

(72) Inventors: Russell Darling, Cambridge (GB); Robert Raymond Taylor, Cambridge (GB)

(73) Assignee: Five AI Limited, Cambridge (GB)

(21) Appl. No.: 18/870,296

(22) PCT Filed: May 31, 2023
(86) PCT No.: PCT/EP2023/064586

§ 371 Date: Nov. 27, 2024

(30) Foreign Application Priority Data
May 31, 2022 (GB) 2208053.5

(51) Int. Cl. G06F 30/15

(52) U.S. Cl. CPC G06F 30/15

(57) ABSTRACT

A computer system for generating a scenario to be run in a simulation environment for testing the behaviour of an autonomous vehicle, the computer system comprising: a rendering component configured to: generate display data for causing a display to render a graphical user interface comprising an image of a driving environment and one or more agents within the driving environment; a parameter generator configured to generate in memory a user-defined parameter set responsive to user input defining the parameter set; and an expression manager configured to store in memory a user-defined expression set, responsive to user input defining the expression set, wherein each expression of the expression set is a user-defined function of one or more parameters of the parameter set; and a scenario generator configured to record the scenario in a scenario database; wherein the graphical user interface is configured to provide multiple agent fields for controlling the behaviour of the one or more agents when the scenario is run in a simulation environment, wherein each agent field is modifiable to associate therewith either a parameter of the user-defined parameter set or an expression of the user-defined expression set; and wherein the recorded scenario comprises the driving environment, the one or more agents, the user-defined parameter set, the user-defined expression set, and any user-defined associations between (i) the multiple agent fields and the user-defined parameter set and (ii) the multiple agent fields and the user-defined expression set, wherein each parameter associated with an agent field is controllable to directly modify an agent behaviour, and each parameter that is included in expression associated with an agent field is controllable to indirectly modify an agent behaviour.

### TECHNICAL FIELD

The present disclosure relates to the generation of scenarios for use in simulation environments for testing the behaviour of autonomous vehicles.

### BACKGROUND

There have been major and rapid developments in the field of autonomous vehicles. An autonomous vehicle is a vehicle which is equipped with sensors and control systems which enables it to operate without a human controlling its behaviour. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. There are different facets to testing the behaviour of the sensors and control systems aboard a particular autonomous vehicle, or a type of autonomous vehicle.

Sensor processing may be evaluated in real-world physical facilities. Similarly, the control systems for autonomous vehicles may be tested in the physical world, for example by repeatedly driving known test routes, or by driving routes with a human on-board to manage unpredictable or unknown context.

Physical world testing will remain an important factor in the testing of autonomous vehicles' capability to make safe and predictable decisions. However, physical world testing is expensive and time-consuming. Increasingly there is more reliance placed on testing using simulated environments. If there is to be an increase in testing in simulated environments, it is desirable that such environments can reflect as far as possible real-world scenarios. Autonomous vehicles need to have the facility to operate in the same wide variety of circumstances that a human driver can operate in. Such circumstances can incorporate a high level of unpredictability.

It is not viable to achieve from physical testing a test of the behaviour of an autonomous vehicle in all possible scenarios that it may encounter in its driving life. Increasing attention is being placed on the creation of simulation environments which can provide such testing in a manner that gives confidence that the test outcomes represent potential real behaviour of an autonomous vehicle.

For effective testing in a simulation environment, the autonomous vehicle under test (the ego vehicle) has knowledge of its location at any instant of time, understands its context (based on simulated sensor input) and can make safe and predictable decisions about how to navigate its environment to reach a pre-programmed destination.

Simulation environments need to be able to represent real-world factors that may change. This can include weather conditions, road types, road structures, road layout, junction types etc. This list is not exhaustive, as there are many factors that may affect the operation of an ego vehicle.

The present disclosure addresses the particular challenges which can arise in simulating the behaviour of actors in the simulation environment in which the ego vehicle is to operate. Such actors may be other vehicles, although they could be other actor types, such as pedestrians, animals, bicycles et cetera.

A simulator is a computer program which when executed by a suitable computer enables a sensor equipped vehicle control module to be developed and tested in simulation, before its physical counterpart is built and tested. A simulator may provide a sensor simulation system which models each type of sensor with which the autonomous vehicle may be equipped. High-fidelity sensor models may provide photorealistic or sensor realistic synthetic sensor data. Other forms of simulation can be implemented without sensor models or with lower-fidelity sensor or perception models. A simulator also provides a three-dimensional environmental model which reflects the physical environment that an automatic vehicle may operate in. The 3-D environmental model defines at least the road network on which an autonomous vehicle is intended to operate, and other actors in the environment. In addition to modelling the behaviour of the ego vehicle, the behaviour of these actors also needs to be modelled.

Simulators generate test scenarios (or handle scenarios provided to them). As already explained, there are reasons why it is important that a simulator can produce many different scenarios in which the ego vehicle can be tested. Such scenarios can include different behaviours of actors. The large number of factors involved in each decision to which an autonomous vehicle must respond, and the number of other requirements imposed on those decisions (such as safety and comfort as two examples) mean it is not feasible to write a scenario for every single situation that needs to be tested. Nevertheless, attempts must be made to enable simulators to efficiently provide as many scenarios as possible, and to ensure that such scenarios are close matches to the real world. If testing done in simulation does not generate outputs which are faithful to the outputs generated in the corresponding physical world environment, then the value of simulation is markedly reduced.

Scenarios may be created from live scenes which have been recorded in real life driving. It may be possible to mark such scenes to identify real driven paths and use them for simulation. Test generation systems can create new scenarios, for example by taking elements from existing scenarios (such as road layout and actor behaviour) and combining them with other scenarios. Scenarios may additionally or alternatively be randomly generated.

However, there is increasingly a requirement to tailor scenarios for particular circumstances such that particular sets of factors can be generated for testing. It is desirable that such scenarios may define actor (agent) behaviour.

### SUMMARY

One aspect of the present disclosure addresses such challenges. According to one aspect, a computer system is provided for generating a scenario to be run in a simulation environment for testing the behaviour of an autonomous vehicle, the computer system comprising:
a rendering component configured to: generate display data for causing a display to render a graphical user interface comprising an image of a driving environment and one or more agents within the driving environment;
a parameter generator configured to generate in memory a user-defined parameter set responsive to user input defining the parameter set; and
an expression manager configured to store in memory a user-defined expression set, responsive to user input defining the expression set, wherein each expression of the expression set is a user-defined function of one or more parameters of the parameter set; and
a scenario generator configured to record the scenario in a scenario database;
wherein the graphical user interface is configured to provide multiple agent fields for controlling the behaviour of the one or more agents when the scenario is run in a simulation environment, wherein each agent field is modifiable to associate therewith either a parameter of the user-defined parameter set or an expression of the user-defined expression set; and
wherein the recorded scenario comprises the driving environment, the one or more agents, the user-defined parameter set, the user-defined expression set, and any user-defined associations between (i) the multiple agent fields and the user-defined parameter set and (ii) the multiple agent fields and the user-defined expression set, wherein each parameter associated with an agent field is modifiable to directly modify an agent behaviour, and each parameter that is included in expression associated with an agent field is modifiable to indirectly modify an agent behaviour.

Expressions allow dependencies to be defined between agents and/or their behaviours. For example, a first agent field (such as a first agent's starting longitudinal position along a road) may be associated with a parameter x and a second agent field (such as a second agent's starting longitudinal position) may be associated with an expression involving the parameter x (e.g. “x−2 m”).

In embodiments, the one or more agents may be rendered in the image in dependence on respective parameter(s) and expression(s) assigned to the multiple agent fields.

The parameter generator may be configured to associate each parameter with a user-defined default value responsive to user input defining the default value of the parameter.

The graphical user interface may be configured to display a calculated default parameter of each expression, as calculated based on the user-defined default value(s) of the one or more parameters of the expression.

Alternatively or in addition, the one or more agents may be rendered in the image based on: the user-defined default value of a parameter assigned to an agent field, and/or a default value of an expression assigned to an agent field, as calculated based on the user-defined default value(s) of the one or more parameters of the expression.

The image may be updated as an expression is defined. For example, the parameter x may be assigned a default value of 7 m by the user, and agents 1 and 2 may be displayed at longitudinal positions 7 m and 7 m−2 m=5 m (the default value of the expression) in the image. Those locations may then be updated automatically as the expression is changed and/or the default parameter value is changed. For example, if the default parameter value is changed from 7 m to 8 m, agent 1's position becomes 8 m and agent 2's becomes 8 m−2 m=6 m, and the image may be updated accordingly.

When the simulation is subsequently run, different values may be sampled for the parameter (e.g. randomly/using Monte Carlo sampling, uniformly, via a directed search of the parameter space etc.), and those values are in turn used to evaluate the expression. For example, in a first instance of the scenario, a value of 3 m may be sampled for x, such that the starting positions for agents 1 and 2 are 3 m and 1 m respectively. In a second instance, a value of 9 m may be sampled for x, such that the starting positions for agents 1 and 2 are 9 m and 7 m respectively. This allows variation, whilst maintaining a desired relationship between the agent position, in a manner that can be intuitively visualised at the design stage.

In embodiments, the graphical user interface may comprise a graphical expression calculator having an expression field for displaying an editable expression, wherein the expression is editable by providing user input denoting an expression element to be inserted in the expression. For example, the expression field may be editable by providing user input denoting one of the following expression elements to be inserted into the expression displayed in the expression field: a parameter of the user-defined parameter set, a numerical value, a mathematical operator, or a pair of parentheses.

The expression element may be inserted at a set position in the editable position, which is not user-modifiable.

The expression field may not be editable, and the expression may only be modifiable by: inserting an expression element at the set position, providing a reverse input to remove the most recently inserted expression element (e.g. only the most recently inserted expression or the N most recently inserted expressions), or providing a clear input to clear the expression field.

For example, in the described embodiments, the expression is editable but the ways in which it can be edited are intentionally limited. In particular, in the described embodiments, the expression field itself is not editable (the user cannot freely select/modify any part of the expression in the expression field); rather, the user can only insert an expression element at a fixed position (generally at the end of the current expression, or within an ‘open’ pair of parentheses at the end of the expression), or remove the most recently inserted expression element(s) (or clear the expression field completely). These restrictions are imposed to ensure the entered expression is valid, which in turn helps to ensure that the resulting scenarios are valid.

The graphical expression calculator may include a plurality of parameter elements, each corresponding to a parameter of the user-defined and selectable to insert the corresponding parameter into the expression displayed in the expression field.

The expression may be editable to insert a pair of parentheses for receiving a single valid entry, the pair of parentheses being automatically closed responsive to receiving a single valid entry, the single valid entry being a combination of expression elements satisfying a validity condition

The graphical expression calculator may include a single bracketing element selectable to insert a pair of parentheses into the expression.

At least one agent field may be assigned an expression involving at least one parameter, and an agent may be displayed in the image of the driving environment in dependence on the expression assigned to the at least one agent field and a default value assigned to the at least one parameter.

At least one agent field may be assigned a parameter, and an agent may be displayed in the image in dependence on the default value of the parameter.

The graphical expression calculator may show, in association with each selectable parameter element of the graphical expression calculator, the user-defined default value of the corresponding parameter.

The graphical expression calculator may include the calculated default value of the expression, which is updated as the expression displayed in the expression field is edited.

The recorded scenario may comprise the user-defined default value of each parameter of the user-defined parameter set.

The visualisation component may be configured to create, responsive to user input for marking one or more locations in the image, the one or agents in the image of the environment.

The parameter generator may be configured to associate each parameter with a user-defined range responsive to user input defining the default range of the parameter, wherein the recorded scenario may comprise the user-defined range of each parameter of the user-defined parameter set.

For testing performance of a robotic system in simulation, the computer system may comprise: a simulator configured to run one or more instances of the scenario in a simulation environment with the robotic system in control of an ego agent of the scenario; a test oracle configured to process each instance of the test scenario and provide one or more outputs for assessing the performance of the robotic system therein; a test orchestration component, wherein the user-defined parameter set of the scenario is exposed to the test orchestration component and the test orchestration component is configured to assign a value to each parameter of the user-defined parameter set for each instance of the scenario, wherein the user-defined expression set is not exposed to the test orchestration component and the simulator is configured to compute each expression based on the value(s) assigned to its one or more parameters by the test orchestration component.

The test orchestration component may be configured to sample the value of each parameter from its user-defined range.

Further aspects provide the above functionality implemented as method steps, and a computer program or set of computer programs for implementing the same.

### BRIEF DESCRIPTION OF FIGURES

For a better understanding of the present invention and to show how the same may be carried into effect, reference will now be made by way of example to the accompanying drawings.

FIG. 1 shows a highly schematic diagram showing how properties may be assigned agents in a scenario.

FIG. 2 shows a highly schematic diagram that illustrates an exemplary structure of a parameter, and a scenario visualiser window.

FIG. 3 shows a highly schematic diagram that illustrates the input of parameters to an expression calculator.

FIG. 4 shows a ‘storyboard’ page of a scenario configuration user interface, which enables user configuration of a scenario for simulation.

FIG. 5 shows an exemplary parameter definition page of the scenario configuration user interface.

FIG. 6 shows an exemplary expression definition page of the scenario configuration user interface.

FIG. 7 shows an instance of the storyboard page of the scenario configuration user interface, in which an expression is called and assigned to a variable.

FIG. 8 shows an instance of the storyboard page of the scenario configuration user interface, in which a drop-down menu is provided for selecting a parameter or expression to be assigned to a variable.

FIG. 9A shows a schematic function block diagram of an autonomous vehicle stack.

FIG. 9B shows a schematic overview of an autonomous vehicle testing paradigm.

FIG. 10 shows a schematic block diagram of a testing pipeline.

FIG. 11 shows a functional block diagram of a scenario editor.

### DETAILED DESCRIPTION

Preferred embodiments will now be described by way of example only.

To conduct simulation-based AV performance testing, it is necessary to define scenarios which can be used to test the behaviour of an ego vehicle in a simulated environment. Scenarios are defined and edited in offline mode, where the ego vehicle is not controlled, and then exported for testing in the next stage of a testing pipeline 7200 which is described below.

In the described examples, a scenario comprises one or more agent (sometimes referred to as actors) travelling along one or more path in a road layout (or, more generally, a driving environment). A road layout is a term used herein to describe any features that may occur in a driving scene and, in particular, includes at least one track along which a vehicle is intended to travel in a simulation. That track may be a road or lane or any other driveable path. A road layout is displayed in a scenario to be edited as an image on which agents are instantiated. Locations in the image are selectable to create agents at those locations. Road layouts, or other scene topologies, may be accessed from a database of scene topologies. Road layouts have lanes etc. defined in them and rendered in the scenario. A scenario is viewed from the point of view of an ego vehicle operating in the scene. Other agents in the scene may comprise non-ego vehicles or other road users such as cyclists and pedestrians. The scene may comprise one or more road features such as roundabouts or junctions. These agents are intended to represent real-world entities encountered by the ego vehicle in real-life driving situations. The described system allows the user to generate interactions between these agents and the ego vehicle which can be executed in the scenario editor and then simulated.

The present description relates to a method and system for generating scenarios to obtain a large verification set for testing an ego vehicle. The scenario generation scheme described herein enables scenarios to be parametrised and explored in a more user-friendly fashion, and furthermore enables scenarios to be reused in a closed loop.

One aim is to ensure that scenarios remain ‘salient’ under different parameterizations (e.g. to ensure that a cut in event actually occurs in a cut in scenario over many different versions of the scenario described by different parameter combinations; this can be engineered, to a degree, using expressions to define appropriate relationships between agents. For example, with independently parameterized agent speeds, a situation might arise where a second agent is meant to approach a first agent and cut in behind it, but never does so, because a particular combination of parameter values means the second agent's speed is lower than that of the first agent, such that the second agent never reaches the second first in a given instance of the scenario; with expressions, this can be avoided, using an expression to relate the second agent's speed to the first agent's speed (or target speed), e.g. assigning a parameter v to to control the first agent's speed (or target speed), and relating this to the second agent's speed (or target speed) via an expression “v+1 m/s” (or some defined other function of v), ensuring that, whatever value is sampled for v, the second agent always moves faster (or attempts to move faster) than the first agent.

In the present system, scenarios are described as a set of interactions. Each interaction is defined relatively between actors of the scene and a static topology of the scene. Each scenario may comprise a static layer for rendering static objects in a visualisation of an environment which is presented to a user on a display, and a dynamic layer for controlling motion of moving agents in the environment. Note that the terms “agent” and “actor” may be used interchangeably herein.

Each interaction is described relatively between actors and the static topology. Note that in this context, the ego vehicle can be considered as a dynamic actor. An interaction encompasses a manoeuvre or behaviour which is executed relative to another actor or a static topology.

In the present context, the term “behaviour” may be interpreted as follows. A behaviour owns an entity (such as an actor in a scene). Given a higher-level goal, a behaviour yields manoeuvres interactively which progress the entity towards the given goal. For example, an actor in a scene may be given a Follow Lane goal and an appropriate behavioural model. The actor will (in the scenario generated in an editor, and in the resulting simulation) attempt to achieve that goal.

Behaviours may be regarded as an opaque abstraction which allow a user to inject intelligence into scenarios resulting in more realistic scenarios. By defining the scenario as a set of interactions, the present system enables multiple actors to co-operate together with active behaviours to create a closed loop behavioural network akin to a traffic model.

The term “manoeuvre” may be considered in the present context as the concrete physical action which an entity may exhibit to achieve its particular goal following its behavioural model.

An interaction encompasses the conditions and specific manoeuvre (or set of manoeuvres)/behaviours with goals which occur relatively between two or more actors and/or an actor and the static scene.

According to features of the present system, interactions may be evaluated after the fact using temporal logic. Interactions may be seen as reusable blocks of logic for sequencing scenarios, as more fully described herein.

Using the concept of interactions, it is possible to define a “critical path” of interactions which are important to a particular scenario. Scenarios may have a full spectrum of abstraction for which parameters may be defined. Variations of these abstract scenarios are termed scenario instances.

Scenario parameters are important to define a scenario, or interactions in a scenario. The present system enables any scenario value to be parametrised. Where a value is expected in a scenario, a parameter can be defined with a compatible parameter type and with appropriate constraints, as discussed further herein when describing interactions. As noted, an aim is to facilitate the design of scenarios that remain salient as their parameters are varied in testing (through the use of expressions).

A scenario is encoded in a scenario description language (SDL), such as OpenSCENARIO or a bespoke SDL.

A scenario can be created and visualised initially, with path(s) and agent(s), using a graphical editor tool described in our co-pending application WO2021244956A1, incorporated herein by reference in its entirety.

At test time, one or more parameters of a scenario are exposed, in the sense that different values of the parameters may be chosen to run variations of a scenarios. Conceptually, a scenario has a parameter space of one or more dimensions, in which each point corresponds to a parameter value set. Parameter values may be randomly chosen (e.g. via Monte Carlo sampling), or a uniform ‘grid’ of parameter values may be chosen in the parameter space. A structured search of the parameter space may also be conducted, referred to as directed testing or directed exploration, with the aim of finding the most salient parameter combinations (according to some defined metric) in as few simulated runs as possible, leveraging knowledge gained in earlier simulations. In that case, the scenario parameter(s) are exposed to a component of the system that is configured to implement a structured search method.

By way of example, reference is made to the 2021 review paper entitled “A Survey of Algorithms for Black-Box Safety Validation of Cyber-Physical Systems” (Corso et al.), whilst outlines a wide range of directed search methods applicable to autonomous cyber-physical systems. Such methods rely on scenarios being parameterized in a logical manner, preferably capturing all salient aspects of the scenario in as few parameters as possible. The efficiency and quality of the search is generally dependent on the number of parameters that are exposed, and the relationship between those parameters.

The present description introduces an additional concept of “expressions” which are related to parameters, but which are not (directly) exposed at test time. Expressions are defined as functions of a parameter (or parameters), and a scenario designer is able to map a scenario variable (such as agent speed, position) to either a parameter or an expression, which will in turn affect how that variable is explored at test time. A graphical user interface (GUI) is provided, in which agent variables are exposed as editable fields in the GUI, where the field may be used to map the variable to a parameter or an expression as desired.

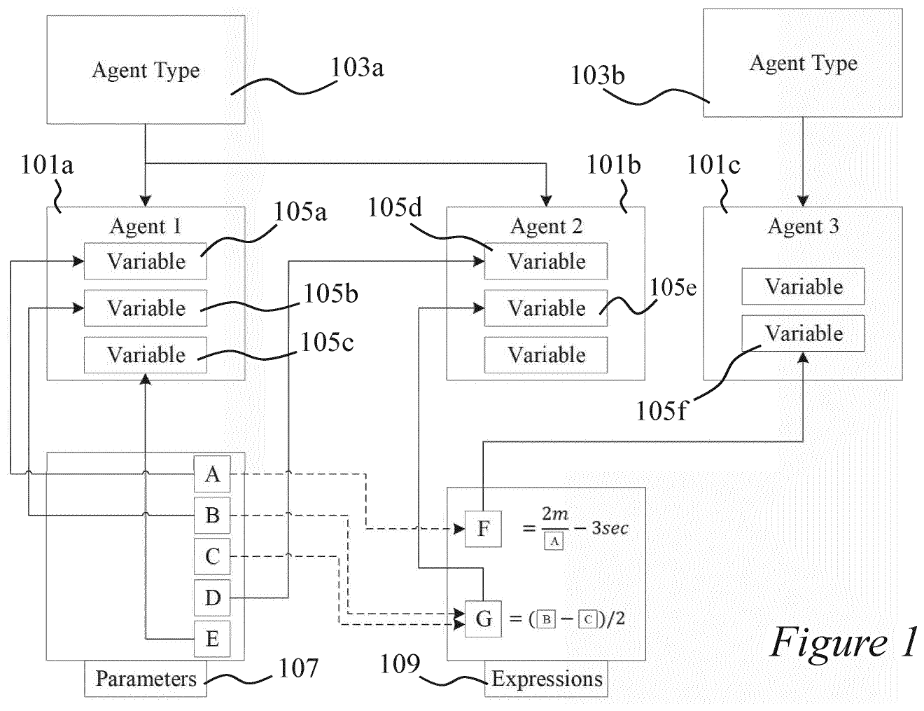

The following description relates to parametrisation of physical and dynamic characteristics and behaviours of agents in a scenario. Parametrisation of scene topologies and road layouts is described in more detail later herein, with further details provided in our co-pending PCT application PCT/EP2022/052123, which is incorporated herein by reference in its entirety. FIG. 1 shows a highly schematic block diagram, which demonstrates how agent behaviours may be configured using “variables”, “parameters” and “expressions”. FIG. 1 shows three exemplary agents: ‘Agent 1’ 101a, ‘Agent 2’ 101b and ‘Agent 3’ 101c, where ‘Agent 1’ 101a and ‘Agent 2’ 101b are of a first agent type 103a and ‘Agent 3’ 101c is of a second agent type 103b. Assignment of agent types 103 to agents 101 is represented by arrows between the agents 101 and agent types 103 of FIG. 1. A user can create parameters in a bespoke parameter set and expressions in a bespoke expression set. An expression can be constructed as a user-defined function of a parameter or parameters of the expression set, in the manner described below.

Note that each block in FIG. 1 may represent a data structure. It will be appreciated that agent type data structures 103 may define a quantity of physical attributes and/or dynamic restrictions of a corresponding agent type, such as size, weight and maximum acceleration etc. Agents 101 assigned a particular agent type may inherit the attributes, behaviours and restrictions defined in the corresponding agent type data structure 103. That is, agent type data structures 103 may define physical and/or dynamic templates for agent types, on which agents 101 may be modelled for simulation.

Each agent data structure 101 may be associated with one or more variable 105. A variable 105 is an abstract data field associated with a particular agent data structure 101, which may be populated to define a dynamic behaviour of a corresponding agent during simulation. In the example of FIG. 1, ‘Agent 1’ 101a is associated with three variables 105a, 105b, and 105c. Such variables 105a, 105b, 105c are exposed, at the design stage, to a scenario designer, via corresponding fields on a scenario editor interface.

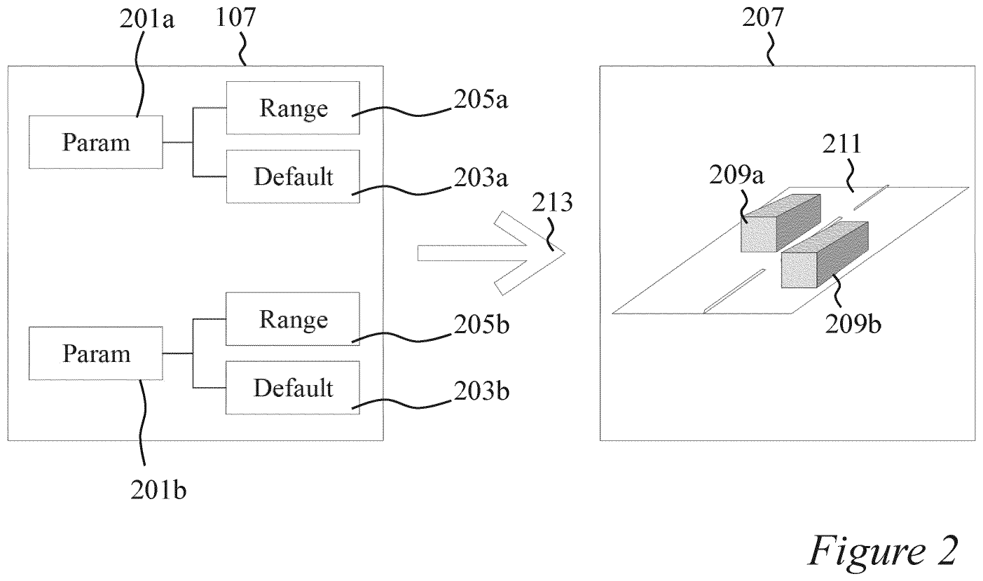

FIG. 1 further shows a parameter data store 107 and an expression data store 109. The parameter data store 107 may comprise one or more user-defined parameter, and/or one or more pre-defined parameter. With reference to FIG. 2, a parameter 201 may include a default value 203 and a range 205, wherein the range may be user-defined or defined by the computing device such that only salient parameter values are sampled during simulation. Note that each parameter 201 in the parameter data store 107 may further include data such as a unit of measurement, e.g., metres per second or kilograms etc. FIG. 2 is described in more detail later herein. As noted, parameters are exposed at test time (after the scenario design has been finalized), to expose a robotic system under testing to different variations of the scenario.

Returning to FIG. 1, the parameter data store 107 is shown to comprise five parameters: ‘A’, ‘B’, ‘C’, ‘D’, and ‘E’. The parameters within the parameter store 107 may be called to populate one or more variable 105 of one or more agent 101. For example, parameter ‘A’ is called in FIG. 1 to populate variable 105a of ‘Agent 1’ 101a, parameter ‘B’ is called to populate variable 105b, parameter ‘E’ is called to populate variable 105c, and parameter ‘D’ is called to populate a variable 105d of ‘Agent 2’ 101b. Note that the calling of parameters to directly populate agent variables 105 is represented in FIG. 1 by arrows from a parameter in the parameter data store 107 to a corresponding variable block 105.

Expressions may also be defined. An expression may be a mathematical expression and may be defined by calling one or more parameter. That is, expressions held in the expression data store 109 may be defined in terms of one or more parameter held in the parameter data store 107. For example, an expression ‘F’ is defined using parameter ‘A’ from the parameter data store. Further, an expression ‘G’ is defined in terms of parameters ‘B’ and ‘C’. Note that the calling of parameters to define an expression is represented in FIG. 1 by dashed lines between the parameter in the parameter data store 107 and the corresponding expression in the expression data store 109 Note that expression ‘F’ is called to populate a variable 105f of ‘Agent 3’ 101c, and expression ‘G’ is called to populate a variable 105e of ‘Agent 2’ 101b.

Note that parameters and expressions may be defined by user input to a tool in a user interface (UI) of a computing device, as is described in more detail later herein. When defining a parameter, a user may further assign a unit of measurement to the defined parameter via the user interface. A parameter may also be defined as a scalar quantity.

Parameters may be called more than once, and for one or more purpose. For example, parameter ‘A’ is called to define variable 105a and is also used in the definition of expression ‘F’. Further, a parameter or variable may be called more than once to populate more than one respective variable 105. In some embodiments, an expression may be definable in terms of another expression, in which case a particular expression may be used more than once and for more than one purpose; e.g., the expression may be called in the definition of a second expression and also called to define a variable.

An expression calculator, a user interface tool for defining expressions, may not provide tools which enable quantities with units to be entered in the expression. In such examples, a user may be required to instead define a parameter that has the desired units, then to call said parameter in the definition of the expression. Alternatively, parameters and expressions may be defined independently of units, and units may instead be attributed to variables. That is, parameters and expressions may dimensionless constants which may be assigned to a variable that is associated with units. It's not necessarily required to use a parameter with units in order to infer the units of the resulting expression. For example, a resulting expression is a “double” (floating point) type that can only be applied to any field/variable that is also declared as a double, regardless of the variable's unit type.

FIG. 2 shows a highly schematic diagram of a parameter data store 107 comprising exemplary parameters 201a and 201b. FIG. 2 also shows a visualiser window 207, in which an image of two agents 209a and 209b are shown on a road layout 211.

The parameter data store 107 of FIG. 2 shows the structure of parameters therein, with each parameter having a default value 203 and a range 205. As discussed earlier, the range may define an upper and lower bound of parameter values which may be sampled in a simulation run. The road layout 211 and configuration of agents 209a and 209b shown in the visualiser window 207 may be indicative of the default values of the parameters 201 in the parameter data store 107. FIG. 2 shows an arrow 213, which represents one or more step performed between defining parameters and seeing a visual rendering of agents on a road layout, according to the default values 203 of parameters 201 in the parameter data store 107.

Note that the one or more step represented by arrow 213 may include defining or one or more expression in terms of one or more of the parameters 201 in the parameter data store 107, and assigning parameters and expressions to variables associated with agents in a scenario.

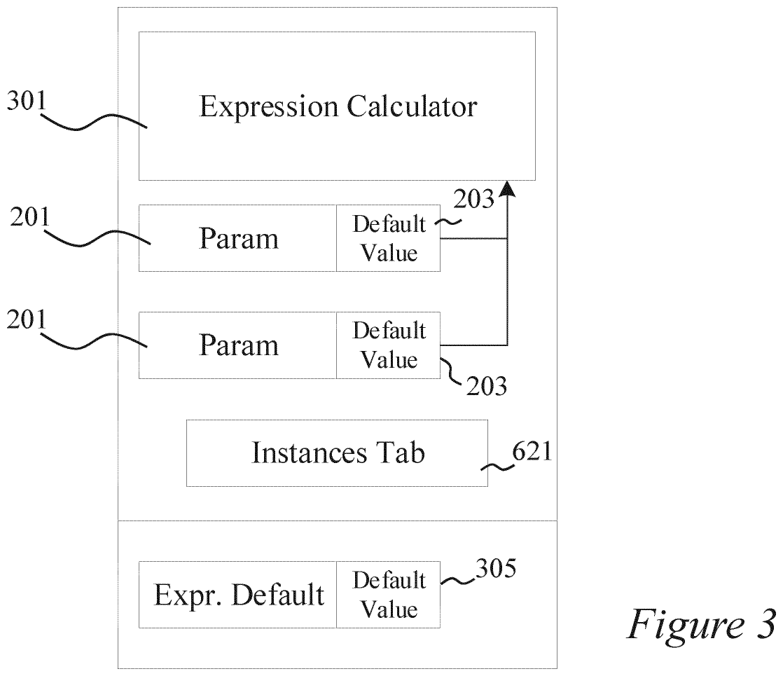

Reference is now made to FIG. 3, which shows a highly schematic diagram of an expression calculator 301, which may be configured to receive user input of parameters 201 to define an expression. As described later herein, a UI may be provided on a computing device, the UI allowing a user to provide inputs and define expressions. Note that when implemented as a UI feature, the expression calculator 301 may include a plurality of selectable buttons corresponding to mathematical operations which may be used to define an expression. Selectable buttons may also be provided for entering values and calling parameters 201 from the parameter data store 107. FIG. 3 shows the input of two exemplary parameters 201, having respective default values 203, to the expression calculator 301. Based on a mathematical expression defined in the expression calculator 301, a default expression value 305 is calculated. The default expression value 305 may be calculated by evaluating the mathematical expression defined in the expression calculator 301 using the default values 203 of the parameters 201 that appear in the mathematical expression.

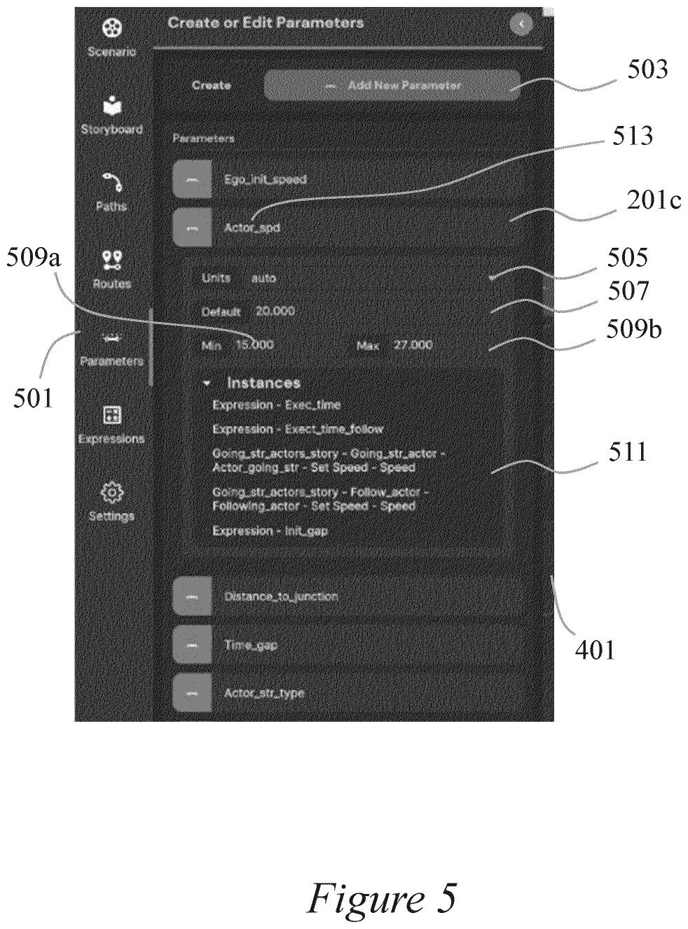

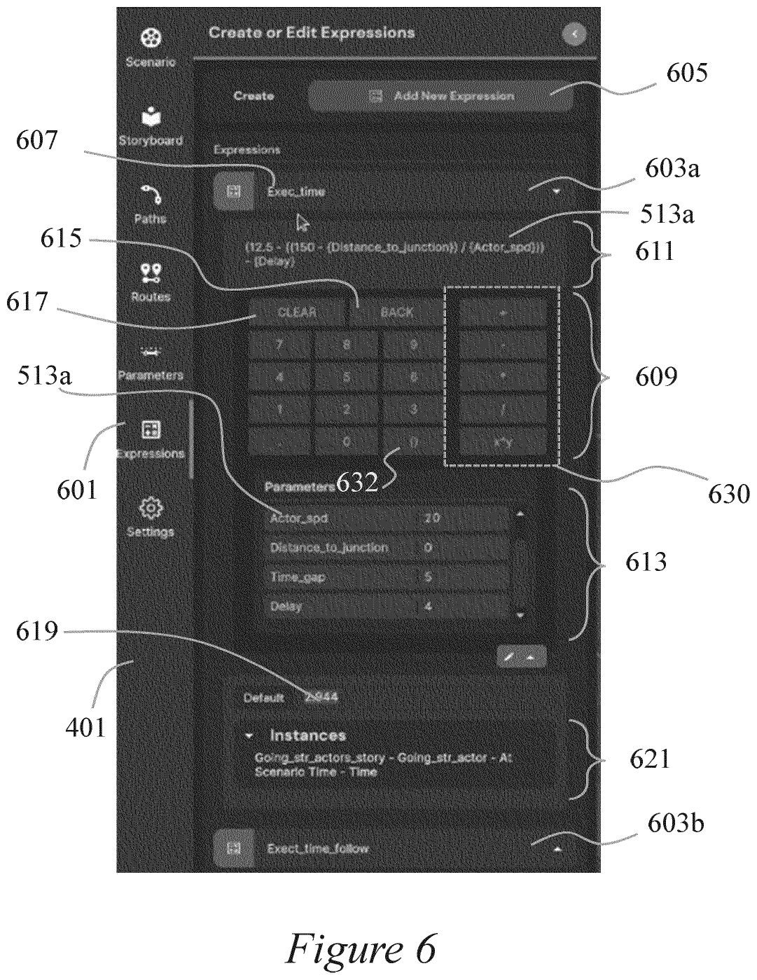

The expression calculator 301 further includes an instances tab 621, which may comprise a list of variables to which a currently edited expression is assigned. Further examples of instances tabs are described in more detail later, with reference to FIGS. 5 and 6.

The range of values at which an expression may be evaluated is dependent on the individual ranges of parameters used to define the expression. Note, however, that the upper and lower bounds of an expression are not necessarily evaluated when the respective upper and lower bounds of constituent parameters are input to the expression.

It would be desirable for users to be able set fields in actions based on calculations performed using existing actions. There is a shared overlap between parameters and expressions as they are both elements that users can map to fields within the GUI.

Expressions are built in memory the form of a tree-like data structure, with each node containing an expression containing a single operator (enum limited to +,−,*,/,\hat{ }) and two operands (either a parameter, int/double value or expression). By way of example, the following expression and its tree-like representation is considered:

$$( x * 10 ) + ( y - 4 ) with x and y as parameters$$

Expression
   Operator:
   Operand 1:
      Expression:
         Operator: *
         Operand 1: X
         Operand 2: 10
   Operand 2
      Expression.
         Operator: −
         Operand 1: y.
         Operand 2: 4

Expressions cannot be nested within other expressions in the described implementations (nested expressions may be possible in other implementations).

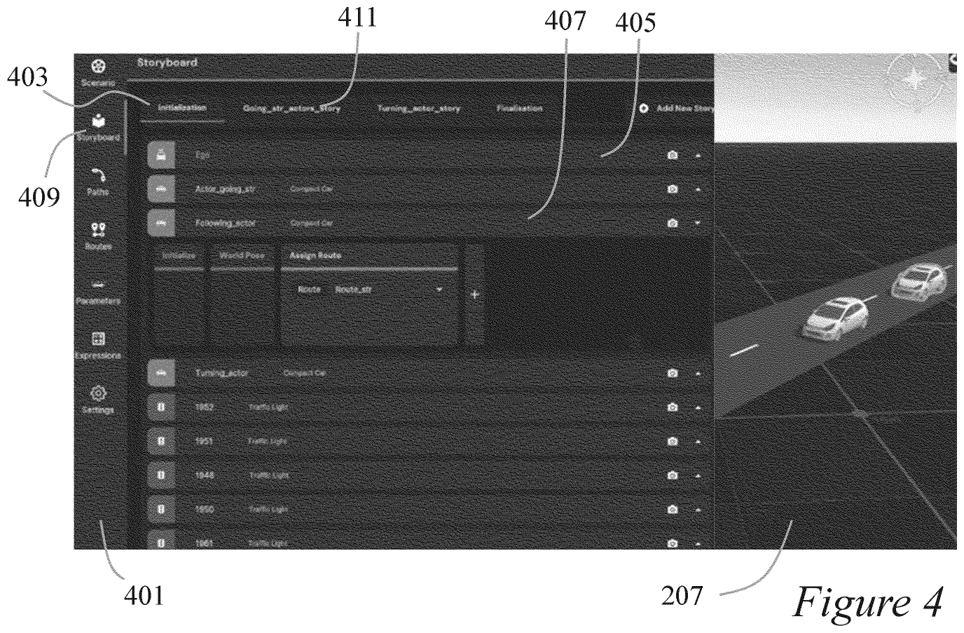

FIGS. 4-8 show a series of exemplary UI tools, with which a user may define one or more agent and assign dynamic behaviours and physical attributes to the one or more agent, for simulation. The agent behaviours and attributes are assigned by defining parameters and expressions and calling those parameters and expressions to populate variables associated with the one or more agent.

FIG. 4 shows an exemplary “storyboard” page 409 of a UI 401. The “storyboard” page 409 of the UI 401 may be used to define one or more agent and its characteristics and behaviours for simulation. In the example of FIG. 4, an ‘initialisation’ tab 403 of the UI 402 is selected, the initialisation tab 403 providing tools that enable user assignment of physical characteristics, such as a predefined agent type, and/or dynamic behaviours, such as a route to be followed by the agent during simulation, to each of the one or more defined agent. Note that a scene topology and road layout on which the agents are to be simulated may be predefined, e.g., from a map database comprising template road layouts, or may be user-defined using UI tools. The UI tools may be as described in our above-mentioned co-pending application PCT/EP2022/052123.

Note that static agents such as traffic lights and road signs may also be defined via the ‘initialisation’ tab 403.

The UI of FIG. 4 further includes a visualiser window 207, in which a graphical representation (image) of a scenario defined in the UI 401 may be displayed. Note, as described with reference to FIG. 2, that the configuration of agents in the visualiser window may be based on default values of parameters and expressions defined by the user and assigned to the agents. Parameters and expressions may be defined and assigned to agent variables using other pages and tabs on the UI 401. For example, the UI 401 of FIG. 4 shows a first story tab 411, which may correspond to one or more of the agents in the scenario.

As is described later herein, agents may be parametrised such that the behaviour of a particular agent is dependent on the behaviour of another. The behaviour of a particular agent may also be linked to the behaviour of another actor by mutual dependence on start and end conditions for the respective behaviours. A story tab 411 may define an independent section of a scenario. Story tabs may include a start condition and an end condition, and may define one or more actor and one or more corresponding action of each actor. The story tab defines a conditional link between each action of each actor, in that the actions are performed upon satisfaction of the start condition, and stop after the end condition.

FIG. 5 shows a parameter definition page 501 displayed on the UI 401. The parameter page 501 of FIG. 5 includes a selectable parameter creation button 503 which, when selected, may allow the user to name and define a value of a parameter 201. In the example of FIG. 5, a plurality of parameters is shown in a list on the parameter page 501, each parameter 201 having a corresponding entry in the list.

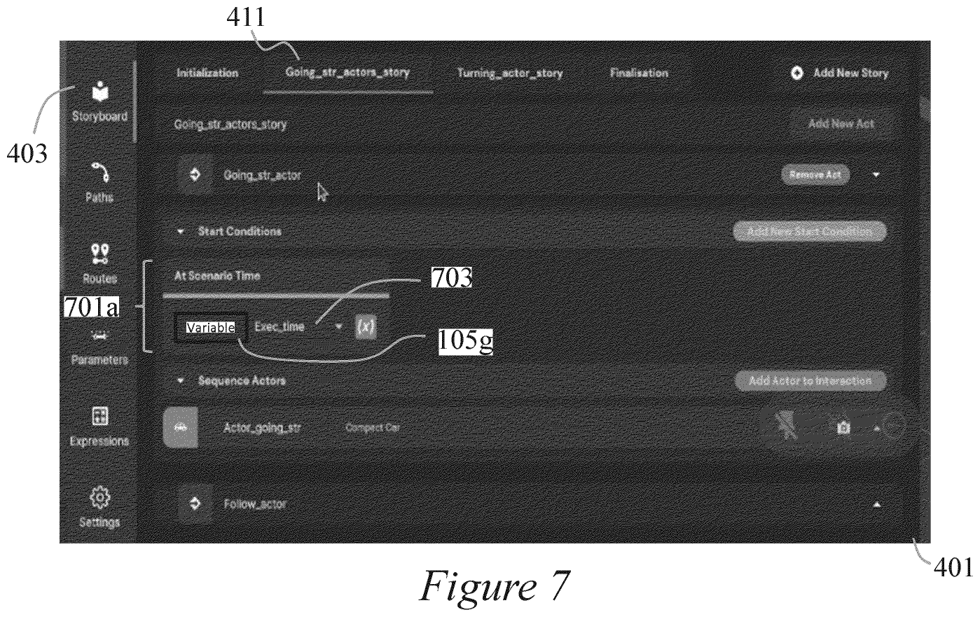

Each entry in the list includes a parameter identifier 513. As is described in more detail with reference to FIG. 7, a parameter 201 may be assigned to a variable 105 by referencing the corresponding parameter identifier 513 in a field configured to define the variable. Each parameter identifier 513 is therefore associated with a data structure address, at which data for the corresponding parameter 201 is stored. During simulation, or in a visualiser window representation of the scenario, data corresponding to a referenced parameter 201 may be retrieved by accessing data stored at the address associated with the referenced parameter identifier 513. Note that the data stored for each parameter may include a default value, a parameter value range, units, and the corresponding parameter identifier.

A parameter 201c, having parameter reference 513 ‘Actor_spd’, is configured in FIG. 5. The parameter page 501 shows an expanded view of the list entry of the ‘Actor_spd’ parameter 201c, the expanded view including a plurality of fields 505, 507, 509a, 509b and 511, configured to receive user input to define or edit aspects of the corresponding parameter 201c.

A unit field 505 is provided on the UI 401, using which a user may define a unit of measurement for the corresponding parameter 201c. The unit field 505 may be a selectable feature of the UI 401 which, when selected, causes a drop-down menu to be displayed on the UI 401, the selectable menu comprising a plurality of predefined units of measurement from which the user may select an appropriate option. As explained previously, however, parameters may be defined as dimensionless constants with no units.

A default field 507 is provided on the UI 401 of FIG. 5, and is configured to receive user input defining a default value 203 of the associated parameter 201c. In the example of FIG. 5, the default value 203 of the parameter 201c is ‘20.000’. A minimum value field 509a and maximum value field 509b are also provided. Fields 509a and 509b are respectively configured to receive user input defining a minimum value and a maximum value that the associated parameter 201c may take during simulation. In the example of FIG. 5, the minimum and maximum values are ‘15.000’ and ‘27.000’ respectively. Values entered to fields 509a and 509b define respective lower and upper bounds of a range 205 associated with the parameter 201c. In examples where a range is computer-defined, e.g., to ensure salience, the range may be determined based on other aspects of the simulation, such as other agent behaviours or the road layout etc.

The parameter definition page 501 further includes a parameter instance field 511. The instance field 511 shows a list of expressions and/or variables which call the associated parameter 201c. The instance field 511 may remain empty unless one more variable calls the parameter 201c, and or one or more expression is defined which calls the parameter 201c.

Reference is now made to FIG. 6, which shows an exemplary expression page 601 provided on the user interface 401. The expression page 601 includes a list comprising a quantity of entries, each entry in the list corresponding to an expression 603 stored in the expression data store 109.

Each entry in the list further includes an expression identifier 607. As briefly described earlier, and as discussed in detail later with reference to FIG. 7, an expression 603 may be assigned to a variable 105 by referencing the corresponding expression identifier 607 in a field configured to define the variable 105. Each expression identifier 607 is therefore associated with a data structure address, at which data for the corresponding expression 603 is stored. During simulation, or in a visualiser window representation of the scenario, the default value, range and other data, such as units, associated with a referenced expression 603 may be retrieved. Retrieval of expression data is enabled by accessing the data structure address associated with the corresponding expression identifier 607.

The expression page 601 includes a ‘new expression’ feature 605, configured to create a new expression. User selection of the ‘new expression’ feature 605 on the UI 401 may allow a user to input a new expression identifier 607 and a mathematical function that defines the new expression 603. When a user creates a new expression by selecting the new expression feature 605, a new entry in the list of expressions may be created in an ‘expanded view’. The expanded view of an expression entry in the list may include UI tools configured to receive user input to define the new expression 603. Existing expression entries in the list shown in FIG. 6 may also be expanded, so that the identifier and/or mathematical function defining existing expressions may be edited.

In the example of FIG. 6 an entry in the list of expressions, corresponding to a first expression 603a with expression identifier 607 ‘Exec_time’, is shown in an expanded view on the expressions page 601. UI tools for editing the expression 603a are also provided on the UI. Note that a second exemplary expression 603b, with expression identifier ‘Exec_time_follow’ is shown in a collapsed view, in which no expression editing tools are displayed.

Tools with which a user may edit an expression 603 (or define a new expression 603) are now described. A calculator input interface 609 is provided with a corresponding calculator display region 611. The calculator input interface 609 includes a plurality of user-selectable buttons which enable a user to enter a mathematical function that defines the corresponding expression 603. Decimal points, parentheses, digits in the range 0-9, and basic mathematical operator symbols, e.g. addition, subtraction, multiplication, division, or index operations may each have a corresponding selectable button provided on the calculator input interface 609.

Upon selection of a particular selectable button on the calculator input interface 609, a corresponding digit or symbol may be displayed in the display region 611. A ‘back’ button 615 and a ‘clear’ button 617 are also provided on the calculator input interface 609. The back button 615 allows a user to delete (undo) the most recent input to the calculator, thereby removing that input from the display region 611. The clear button 617 may be selected to remove all input, thus removing all digits and symbols from the display region 611. If a user wishes to undo an earlier input, they must first undo all other input(s) since then.

Though the user input device to the expression calculator is not shown in FIG. 6, it will be appreciated that a keyboard device may be used to interact with the input interface 609. Each of the selectable buttons on the calculator interface 609 may have a designated ‘hotkey’, a corresponding button on a physical keyboard device, wherein the use of a particular hotkey on the keyboard device may cause a corresponding input to the calculator interface 609, as if the corresponding selectable button on the interface 609 had been selected.

The keyboard input is strictly a “hotkey” kind of interaction (as opposed to simply typing into the expression display 611, which the user cannot edit directly using the keyboard. A benefit of this specific calculator-like interface is that it ensures the resulting expression is valid (free from typographical errors or malformed mathematical operations).

The expanded view of an entry in the list of expressions 603 in FIG. 6 further includes a parameter index 613. The parameter index is shown as a table comprising a quantity of rows, each row in the parameter index 613 corresponding to a parameter in the parameter store 107 and displaying the parameter identifier 513 and default value for that parameter.

Each row in the parameter index 613 may be a selectable feature of the UI 401 which, when selected, may call the associated parameter 201 in the expression 603. That is, selection of a particular parameter row in the parameter index 613 may indicate a corresponding address in the parameter store 107, from which a parameter value may be retrieved to evaluate the expression 603. On the expression page 601 of the UI 401, selection of a particular parameter row in the parameter index 613 may cause display of the corresponding parameter identifier 513 in the expression calculator display 611. In the example of FIG. 6, an exemplary selectable parameter identifier 513a (parameter button) corresponding to the ‘Actor_spd’ parameter is displayed both in a row of the parameter index 613, and in the function displayed in the display region 611 of the expression calculator. It will be appreciated therefore that the Exec_time expression 603a, which is being edited in the example of FIG. 6, is dependent on the Actor_spd variable; that is, the value of the Exec_time expression 603a is at least in part dependent on a value taken by the Actor_spd parameter.

To help understand the result of the calculation, default values are shown next to the parameters and the expected result of the expression (based on the default values) is displayed on the calculator screen. Hence, the expression page 601 includes an expression default field 619, which displays a default value of the associated expression 603. The default value of an expression may be number output when the expression 603 is evaluated using the respective default values of parameters 201 called in the expression 603.

The expressions page 601 further includes an expression instance field 621. The instance field 621 shows a list of variables in which the associated expression 603 is called. The instance field 621 may remain empty unless one more variable calls the expression 201.

The user can select parameters to be included by selecting one of the parameter buttons (e.g. 513a). In addition, a user can add an operator from the set (+,−,*,/,\hat{ }) [add, subtract, multiply, divide and power] using corresponding operator buttons 630. A sub-expression button 632 (the bracket or “( )” button) can be used to add a new sub expression.

When the ( ) is pressed, the subsequent expression entry is contained within the parenthesis. It automatically closes the parenthesis after a single valid entry (e.g. “(a+b)”), which is to say a subexpression satisfying some validity condition.

Specifically, when the ( ) button 632 is selected a pair of brackets (parentheses) is inserted. The sub-expression is automatically ‘closed’ once a valid subexpression is entered. So, for example, if “( )” is pressed, followed by “Actor_spd”, “+” and “5”, the sub-expression will be automatically closed as “(Actor_spd+5)”; if the user then presses, say “*” and “Time_gap”, this will be entered as “(Actor_spd+5)*Time_gap” [not (Actor_spd+5*Time_gap)] because the subexpression “Actor_spd+5” is valid. All of these inputs can alternatively be entered using hotkeys. Further worked examples are set out in the Annex at the end of the description.

To make the interface act more like a traditional calculator and obey the underlying SDL structure it will make the following decisions automatically.

Pressing an operator button after an operator symbol in the expression will change that symbol to be the key just pressed. For example, if the last symbol in the expression is “+” and the “−” button is pressed, the “+” will change to “−”.

Adding a third item to an expression will automatically bracket the first two, e.g. 1+2*3 will automatically become (1+2)*3.

The expression calculator input interface 609 does not include selectable function navigation tools. That is, no selectable buttons on the calculator input interface 611 enable user navigation to a particular point in the function shown on the calculator display region 611, without deleting at least the portion of the function that follows that particular point. The only navigation tools provided on the calculator input interface 609 are the ‘Back’ 615 and ‘Clear’ 617 buttons, which only allow a user to edit a particular point in the function by deleting content back to that point, or by removing all content and re-inputting the function.

Expressions may be defined at different levels of complexity. More complicated expressions may typically include more parameters or other independent variables, more mathematical operators, and more complex hierarchies of parentheses. As the complexity of a function defining an expression increases, so too does the difficulty of entering such a function to a calculator interface 609 with limited navigational tools. For example, input of a complicated function to the calculator interface 609, having a typically complex hierarchy of parentheses, may require large user effort and/or several input attempts before the correct format is entered.

As mentioned previously, the overriding motive for such a restricted interface is to ensure that the user doesn't create invalid expressions, and those considerations apply to expressions of any level of complexity. The design is a trade-off of usability for the integrity of the scenario. In other implementations, the user interface may be extended with enhancements to support the creation of more complicated expressions.

The image in the visualizer window 207 is updated at the field assignments change (e.g. to replace a parameter assigned to a field with another parameter or expression in a field, or to replace an expression assigned to a field with a parameter or another expression). In particular, agent position (location and/or orientation) variables may be visualised based on their assigned fields/parameters. Motion variables may also be visualised using a suitable visual mechanism. The default parameter values and default expression values may be used for the visualisation, with the visualisation updated as the default values are changed (the default value of an expression is changed by changing the default value of one of its constituent parameters).

For example, an agent with a longitudinal position variable assigned to parameter x, with default value of 5 m, may be shown 5 m along the road at a given time step (e.g. t=0). A second agent with a longitudinal position variable assigned to the expression “x−2 m” may be shown 5 m−2 m=3 m along the road at that time step.

The scenario visualisation 207 is not necessarily static. For example, a moving image may be shown, or a series of images may be shown (e.g. simultaneously or sequentially) representing at different time steps of the scenario, it may be possible to update the image to show the scenario at different time steps. In such cases, default values assigned or calculated for motion fields can control the image(s) at different time steps. For example, an agent may be shown in the image (or images) at different time steps, at locations defined by the default values of parameters/expressions assigned to its speed and position variables. In this case, expressions assigned to motion fields, e.g. be used to define motion relationships between agents (e.g. defining agent 2's speed in terms of agent 1's speed), are visualised at the design stage. More complex expressions can be used to define more complex relationships (e.g. speed in terms of position and time), which can also be visualised. Motion variables could alternatively or additionally be indicated using other visualisation mechanisms (such as arrows representing motion vectors).

FIG. 7 shows an instance of the UI 401, displaying the storyboard page 403. In the example of FIG. 7, the first story tab 411, entitled ‘Going_str_actors_story’, is selected. The storyboard interface structure is designed guided by the OpenSCENARIO file format (see https://www.asam.net/index.php?eID=dumpFile&t-f&f=4908&token=ae9d9b44ab9257e817 072a653b5d5e98ee0babf8#_storyboard_and_entities for an overview, incorporated herein by reference in its entirety).

FIG. 7 shows a variable configuration block 701a, which is a user interface feature configured to receive user input assigning a parameter or expression to a variable 105 associated with the variable configuration block 701a. In the example of FIG. 7, the variable configuration block 701a is associated with a start condition variable 105g. The start condition variable 105g may define an instance in a scenario at which a particular event or agent behaviour begins. Note that the ‘point in a scenario’ at which the start condition is met may be any suitable spatial, temporal or dynamic condition, such as a point in time, a distance travelled, a target speed etc. The variable configuration block 701a of FIG. 7 shows the assignment of a parameter to a scenario condition variable, defining a scenario condition. Whilst the variable 105 being defined in FIG. 7 is defined by only one parameter, it will be appreciated that in general, a variable configuration block 701 may include a plurality of fields, with a plurality of aspects of the associated variable being defined by a corresponding plurality of constants, parameters and/or expressions. For example, an action or condition may have multiple variables, one or some of which might be assigned to expression(s), other(s) to parameter(s), and yet other(s) to constant(s) (all in one variable configuration block).

A parameter 201 or expression 603 may be assigned to a variable 105 by populating a field 703 in the variable configuration block 701 with an identifier of the parameter or expression. Note that the parameter or expression is held in a respective data store 107, 109. In FIG. 7, the field 703 associated with variable 105g is populated with a parameter identifier: ‘Exec_time’. In effect, assignment of a parameter or expression to a variable designates a data structure address from which values for the variable are to be retrieved. For example, the data structure address indicated by an identifier may store a default value of the assigned parameter or expression, using which the system may generate a representation of the scenario in a visualiser window. The referenced data structure address may also comprise a range for the assigned parameter or expression, within which a value may be sampled to generate a simulation run.

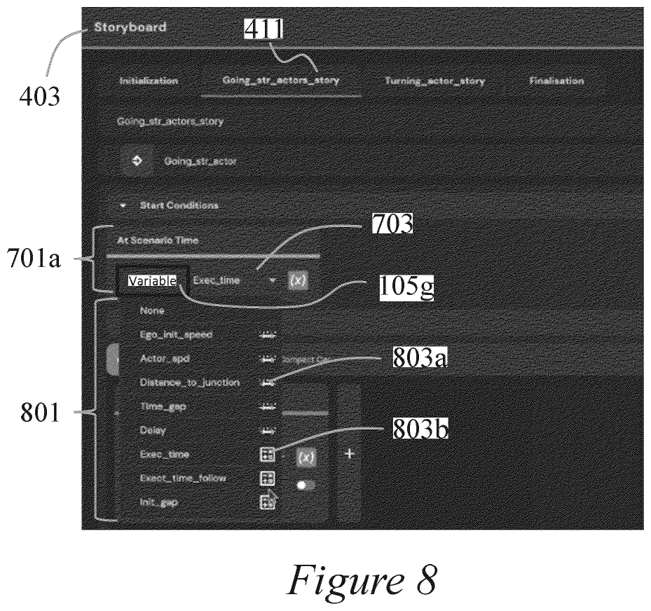

The field 703 may be populated manually. For example, the field 703 may be configured to receive user input from a keyboard device, the input being an identifier of a parameter or variable to be assigned. Alternatively, the field 703 may be selectable to open a drop-down menu, as shown in FIG. 8.

FIG. 8 shows the same example of the user interface 401 as is shown in FIG. 7. In FIG. 8, the field 703 is selected to open a drop-down menu 801, the menu 801 comprising a plurality of entries. Each entry in the menu 801 corresponds to a parameter or expression, and shows an identifier of its corresponding parameter or expression. Each entry in the menu 801 may be a selectable option. Upon selection of a particular entry, the field 703 is populated with the identifier shown in the selected entry, and the parameter or expression corresponding to the selected entry is assigned to the variable 105g.

Each entry in the menu 801 includes an icon 803, which indicates whether the identifier shown in that entry corresponds to a parameter or an expression. A first icon type 803a is displayed on entries in the menu 801 which are associated with a parameter in the parameter data store. A second icon type 803b is displayed on entries which are associated with an expression in the expression data store.

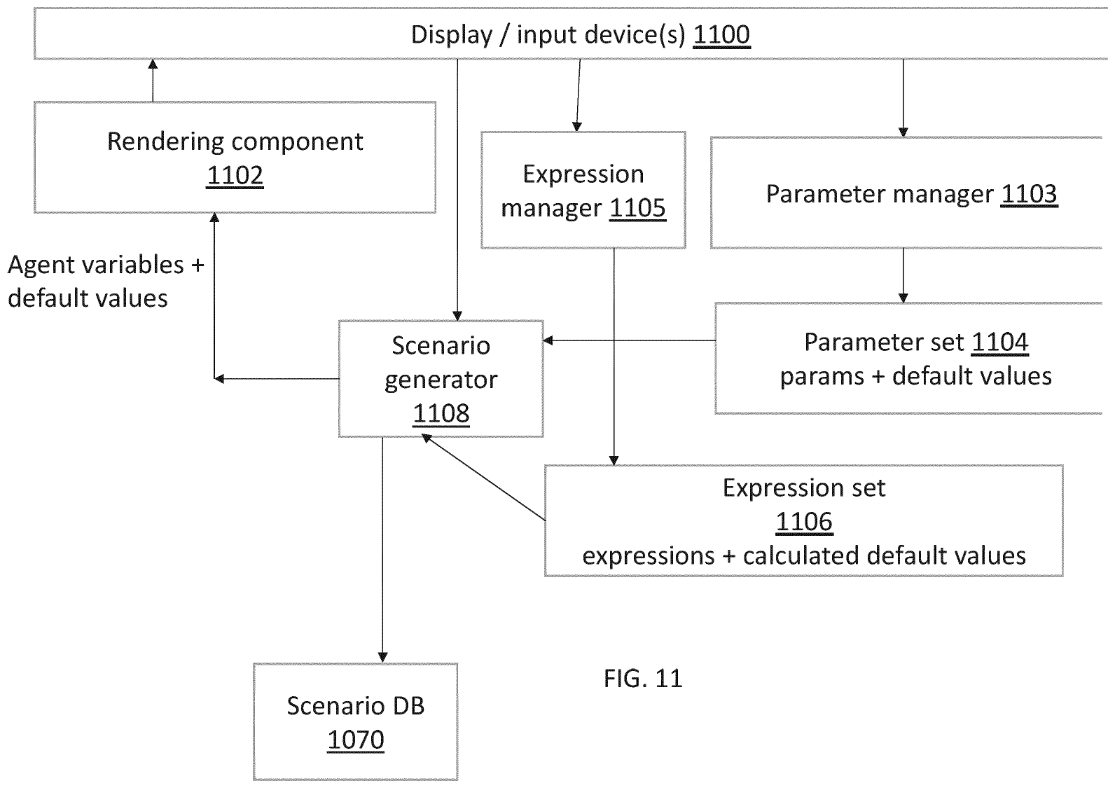

FIG. 11 shows a block diagram of a scenario editor, shown to comprise a rendering component 1102, a parameter manager 1103, an expression manager 1105 and a scenario generator 1108. The rendering component 1102, expression manager 1103 and parameter manager 1105 are shown coupled to a set of input/output equipment 1100, comprising at least one display and at least one input device (touchscreen, keyboard, mouse, trackpad etc.). The rendering component 1102 renders the GUI, including the visualisation image. The scenario generator is configured to manage the scenario, including agents added to the scenario, and types their variables. The parameter manager 1103 manages parameters and their default values, stored as a parameter set 1104. The expression manager 1105 manages expressions and calculates their default values. The scenario generator 1108 maintains associations between agent variables and parameters/expressions, and causes the visualisation image to be updated based on the default values of the parameters/expressions assigned to variables. The scenario generator 1108 is also responsible for recording the scenario in a scenario database 1070 for use in simulation. The recorded scenario encapsulates the user-defined parameter(s) and the relationships embodied in the user-defined expression(s). The default parameter value(s) may also be recorded, e.g. for use in rendering visualisations/previews of the scenario elsewhere in the system. As will be appreciated, FIG. 11 is highly-schematic, and does not necessarily reflect the code or program structure of the scenario editor. Functional blocks in FIG. 11 generally denote certain subsets of the scenario editor's functionality.

### Deployment in Simulation

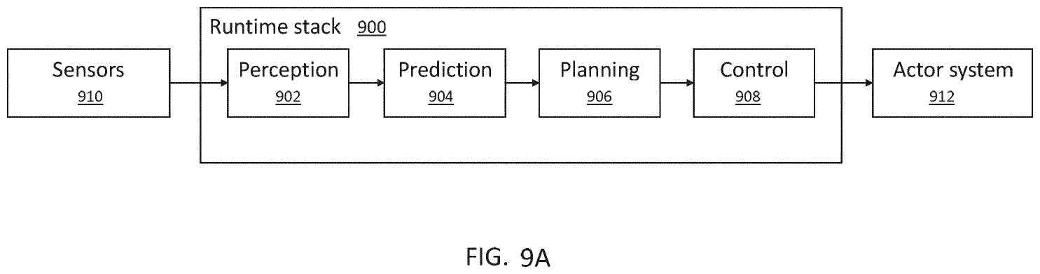

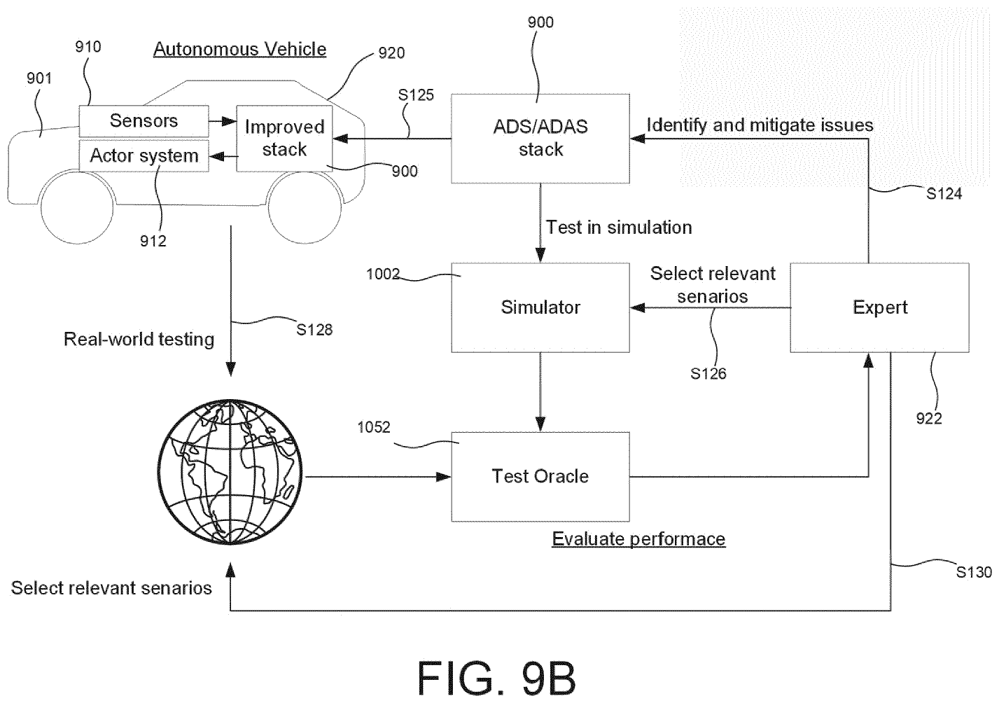

FIG. 9A shows, by way of context, a highly schematic block diagram of an AV runtime stack 900. The run time stack 900 is shown to comprise a perception system 902, a prediction system 904, a planning system (planner) 906 and a control system (controller) 908.

In a real-world context, the perception system 902 receives sensor outputs from an on-board sensor system 910 of the AV, and uses those sensor outputs to detect external agents and measure their physical state, such as their position, velocity, acceleration etc. The on-board sensor system 110 can take different forms but generally comprises a variety of sensors such as image capture devices (cameras/optical sensors), lidar and/or radar unit(s), satellite-positioning sensor(s) (GPS etc.), motion/inertial sensor(s) (accelerometers, gyroscopes etc.) etc. The onboard sensor system 910 thus provides rich sensor data from which it is possible to extract detailed information about the surrounding environment, and the state of the AV and any external actors (vehicles, pedestrians, cyclists etc.) within that environment. The sensor outputs typically comprise sensor data of multiple sensor modalities such as stereo images from one or more stereo optical sensors, lidar, radar etc. Sensor data of multiple sensor modalities may be combined using filters, fusion components etc. The perception system 902 typically comprises multiple perception components which co-operate to interpret the sensor outputs and thereby provide perception outputs to the prediction system 902. In a simulation context, synthetic sensor data may be fed to the perception system 902, as generated using high-fidelity sensor models. Alternatively, the perception system 902 (or a portion or portions thereof) may be replaced with a surrogate model(s) operating on lower-fidelity inputs from the simulator.

Predictions computed by the prediction system 904 are provided to the planner 906, which uses the predictions to make autonomous driving decisions to be executed by the AV in a given driving scenario. A core function of the planner 906 is the planning of trajectories for the AV (ego trajectories), taking into account predicted agent motion. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown). The controller 908 executes the decisions taken by the planner 906 by providing suitable control signals to an on-board actor system 912 of the AV. In particular, the planner 906 plans trajectories for the AV and the controller 908 generates control signals to implement the planned trajectories.

The example of FIG. 9A considers a relatively “modular” architecture, with separable perception, prediction, planning and control systems 902-908. The extent to which the various stack functions are integrated or separable can vary significantly between different stack implementations—in some stacks, certain aspects may be so tightly coupled as to be indistinguishable. At the extreme, in so-called “end-to-end” driving, perception, prediction, planning and control may be essentially inseparable. Unless otherwise indicated, the perception, prediction planning and control terminology used herein does not imply any particular coupling or modularity of those aspects.

It will be appreciated that the term “stack” encompasses software, but can also encompass hardware. In simulation, software of the stack may be tested on a “generic” off-board computer system, before it is eventually uploaded to an on-board computer system of a physical vehicle. However, in “hardware-in-the-loop” testing, the testing may extend to underlying hardware of the vehicle itself. For example, the stack software may be run on the on-board computer system (or a replica thereof) that is coupled to the simulator for the purpose of testing. In this context, the stack under testing extends to the underlying computer hardware of the vehicle. As another example, certain functions of the stack 900 (e.g. perception functions) may be implemented in dedicated hardware. In a simulation context, hardware-in-the loop testing could involve feeding synthetic sensor data to dedicated hardware perception components.

FIG. 9B shows a highly schematic overview of a testing paradigm for autonomous vehicles. An ADS/ADAS stack 900, e.g. of the kind depicted in FIG. 9A, is subject to repeated testing and evaluation in simulation, by running multiple scenario instances in a simulator 1002, and evaluating the performance of the stack 900 (and/or individual subs-stacks thereof) in a test oracle 1052. The output of the test oracle 1052 is informative to an expert 922 (team or individual), allowing them to identify issues in the stack 900 and modify the stack 900 to mitigate those issues (S124). The results also assist the expert 922 in selecting further scenarios for testing (S126), and the process continues, repeatedly modifying, testing and evaluating the performance of the stack 900 in simulation. The improved stack 900 is eventually incorporated (S125) in a real-world AV 901, equipped with a sensor system 910 and an actor system 912. The improved stack 900 typically includes program instructions (software) executed in one or more computer processors of an on-board computer system of the vehicle 901 (not shown). The software of the improved stack is uploaded to the AV 901 at step S125. Step S125 may also involve modifications to the underlying vehicle hardware. On board the AV 901, the improved stack 900 receives sensor data from the sensor system 910 and outputs control signals to the actor system 912. Real-world testing (S128) can be used in combination with simulation-based testing. For example, having reached an acceptable level of performance through the process of simulation testing and stack refinement, appropriate real-world scenarios may be selected (S130), and the performance of the AV 101 in those real scenarios may be captured and similarly evaluated in the test oracle 1052.

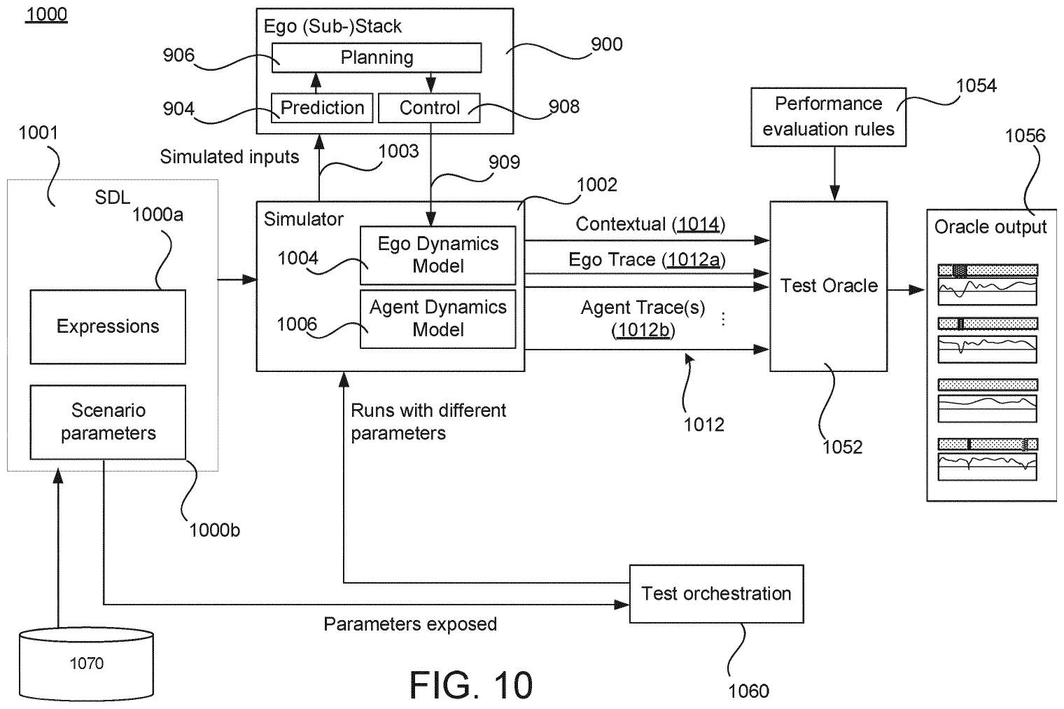

FIG. 10 shows a schematic block diagram of a testing pipeline 1000. The testing pipeline 1000 is shown to comprise the simulator 1002 and the test oracle 1052. The simulator 1002 runs simulated scenarios for the purpose of testing an AV run time stack 900, and the test oracle 1052 evaluates the performance of the stack (or sub-stack) on the simulated scenarios. As discussed, it may be that only a portion (or portions) of the run-time stack is tested, but for simplicity, the following description refers to the (full) AV stack 1000 throughout.

As described previously, the idea of simulation-based testing is to run a simulated driving scenario 1001, encoded in SDL, that an ego agent must navigate under the control of the stack 9000 being tested. The scenario 1001 includes one or more user-defined parameters 1000b and one or more expressions 1000a. The user-defined relationships between variables of the scenario 1001 (such as agent's positions, orientation, speeds, accelerations etc.), the expressions 1001a and the parameters 1000b are recorded in the scenario 1001.

Simulated inputs 1003 are used (directly or indirectly) as a basis for decision-making by the planner 908. As noted, the simulated inputs 1003 could be high-fidelity synthetic sensor data, or lower-fidelity inputs. For example, a surrogate model of all or part of the perception system 902 may be used in testing, operating on lower-fidelity inputs. The controller 908, in turn, implements the planner's decisions by outputting control signals 909. In a real-world context, these control signals would drive the physical actor system 912 of AV. In simulation, an ego vehicle dynamics model 1004 is used to translate the resulting control signals 909 into realistic motion of the ego agent within the simulation, thereby simulating the physical response of an autonomous vehicle to the control signals 909. Alternatively, a simpler form of simulation assumes that the ego agent follows each planned trajectory exactly between planning steps. This approach bypasses the control system 908 (to the extent it is separable from planning) and removes the need for the ego vehicle dynamic model 1004. This may be sufficient for testing certain facets of planning. One or more agent dynamics models 1006 may be used to provide realistic agent behaviour in simulation.

The output of the simulator 1002 for a given simulation includes an ego trace 1012a of the ego agent and one or more agent traces 1012b of the one or more external agents (traces 1012). Each trace 1012a, 1012b is a complete history of an agent's behaviour within a simulation having both spatial and motion components. For example, each trace 1012a, 1012b may take the form of a spatial path having motion data associated with points along the path such as speed, acceleration, jerk (rate of change of acceleration), snap (rate of change of jerk) etc. Additional contextual data 1014 pertaining to the traces is provided.

The test oracle 1052 receives the traces 1012 and the contextual data 1014, and scores those outputs in respect of a set of performance evaluation rules 1054. The test oracle 1056 provides. The test oracle computes an output 1056 denoting performance of the stack 900 with respect to the driving rules 1054.

The scenario 1001 is created using the above scenario editor, and recorded in the scenario database 1070. The scenario database 1070 may contain a large number of recorded scenarios.

The user-defined parameters 1000b of the scenario 1001 are exposed to a component 1060 of the system responsible for determining variations of the scenario 1001 (test orchestration component). For example, the test orchestration 1060 component may select values of the parameters 1000b randomly (e.g. based on Monte Carlo sampling), via a uniform grid search, using directed testing/directed exploration methods etc. An instance or ‘run’ of a scenario refers to an instantiation in a simulator with a particular set of parameter value(s). Hence, scenario variables with assigned parameters are controlled directly by controlling (that is, sampling values of) those parameters.

Parameter values are sampled based on their user-defined ranges. For example, a parameter value may be uniformly or randomly selected from its user-defined range.

The expressions 1000a are not exposed to the test orchestration component 1060 in this manner. Rather, the expressions 1000a are evaluated as needed based on the sampled parameter values to compute the simulation based on the parameter values sampled in a given run. Hence, scenario variables with assigned expressions are controlled indirectly by sampling values of the parameters contained in those expressions, and using the sampled values to calculate values of the expressions. This allows greater control over a scenario, e.g. to ensure that two agents remain a certain distance apart (even if their starting locations change between runs), or to ensure an event such as a cut in or overtake occurs by relating agents' speeds to one another (e.g. to avoiding a situation where an overtaking agent never reaches the forward agent it is supposed to overtake).

The agent parameters/expressions, and their sampled/calculated values, may for example form inputs to the agent dynamics models 1006.

References herein to components, functions, modules and the like, such as components 1102, 1103, 1105, and 1108 of the scenario editor in FIG. 11, denote functional components of a computer system which may be implemented at the hardware level in various ways. A computer system comprises execution hardware which may be configured to execute the method/algorithmic steps disclosed herein and/or to implement a model trained using the present techniques. The term execution hardware encompasses any form/combination of hardware configured to execute the relevant method/algorithmic steps. The execution hardware may take the form of one or more processors, which may be programmable or non-programmable, or a combination of programmable and non-programmable hardware may be used. Examples of suitable programmable processors include general purpose processors based on an instruction set architecture, such as CPUs, GPUs/accelerator processors etc. Such general-purpose processors typically execute computer readable instructions held in memory coupled to or internal to the processor and carry out the relevant steps in accordance with those instructions. Other forms of programmable processors include field programmable gate arrays (FPGAs) having a circuit configuration programmable through circuit description code. Examples of non-programmable processors include application specific integrated circuits (ASICs). Code, instructions etc. may be stored as appropriate on transitory or non-transitory media (examples of the latter including solid state, magnetic and optical storage device(s) and the like).

ANNEX
Calculator Interface Worked Examples

```
Target (x * 20) − 5
  Press x param button.
    x
  Press multiply button
    x *
  Type 20 using the number pad
    x * 20
  Press minus button
    (x * 20) −
  Type 5 in numeric input and press insert button
    (x * 20) − 5
Target (x * 10) + (y\hat{ }2)
  Press x param button
    x
  Press multiply button
    x *
  Type 10 using the number pad
    x * 10
  Press plus button
    (x * 10) +
  Press ( ) button
    (x * 10) + (_)
  Press y button
    (x * 10) + (y)
  Press \hat{ } button
    (x * 10) + (y \hat{ })
  Type 2 in numeric input and press insert button
    (x * 10) + (y²)
```

1. A computer system for generating a scenario to be run in a simulation environment for testing behaviour of an autonomous vehicle, the computer system comprising:
at least one memory storing computer-readable instructions; and
at least one processor coupled to the at least one memory and configured to execute the computer-readable instructions, which upon execution cause the at least one processor to implement:
a rendering component configured to: generate display data for causing a display to render a graphical user interface comprising an image of a driving environment and one or more agents within the driving environment;
a parameter generator configured to generate in memory a user-defined parameter set responsive to user input defining the parameter set;
an expression manager configured to store in memory a user-defined expression set, responsive to user input defining the expression set, wherein each expression of the expression set is a user-defined function of one or more parameters of the parameter set; and
a scenario generator configured to record the scenario in a scenario database;
wherein the graphical user interface is configured to provide multiple agent fields for controlling the behaviour of the one or more agents when the scenario is run in a simulation environment, wherein each agent field is modifiable to associate therewith either a parameter of the user-defined parameter set or an expression of the user-defined expression set; and
wherein the recorded scenario comprises the driving environment, the one or more agents, the user-defined parameter set, the user-defined expression set, and any user-defined associations between (i) the multiple agent fields and the user-defined parameter set and (ii) the multiple agent fields and the user-defined expression set, wherein each parameter associated with an agent field is controllable to directly modify an agent behaviour, and each parameter that is included in expression associated with an agent field is controllable to indirectly modify an agent behaviour.

2. The computer system of claim 1, wherein the graphical user interface comprises a graphical expression calculator having an expression field for displaying an editable expression, wherein the expression is editable by providing user input denoting an expression element to be inserted in the expression.

3. The computer system of claim 2, wherein the expression is editable by providing user input denoting one of the following expression elements to be inserted into the expression displayed in the expression field:
a parameter of the user-defined parameter set,
a numerical value,
a mathematical operator, or
a pair of parentheses.

4. The computer system of claim 2, wherein the expression element is inserted at a set position in the editable expression, which is not user-modifiable.

5. The computer system of claim 2, wherein the expression field is not editable, wherein the expression is only modifiable by:
inserting an expression element at a set position in the editable expression,
providing a reverse input to remove a most recently inserted expression element, or
providing a clear input to clear the expression field.

6. The computer system of claim 2, wherein the graphical expression calculator includes a plurality of parameter elements, each corresponding to a parameter of the user-defined and selectable to insert the corresponding parameter into the expression displayed in the expression field.

7. The computer system of claim 2, wherein the expression is editable to insert a pair of parentheses for receiving a single valid entry, the pair of parentheses being automatically closed responsive to receiving a single valid entry, the single valid entry being a combination of expression elements satisfying a validity condition.

8. The computer system of claim 2, wherein the graphical expression calculator includes a single bracketing element selectable to insert a pair of parentheses into the expression.

9. The computer system of claim 1, wherein the parameter generator is configured to associate each parameter with a user-defined default value responsive to user input defining the default value of the parameter.

10. The computer system of claim 9, wherein the graphical user interface is configured to display a calculated default value of each expression, as calculated based on the default value of the user-defined default value(s) of the one or more parameters of the expression.

11. The computer system of claim 9, wherein the graphical user interface comprises a graphical expression calculator having an expression field for displaying an editable expression, wherein the expression is editable by providing user input denoting an expression element to be inserted in the expression; and
wherein the graphical expression calculator shows, in association with each selectable parameter element of the graphical expression calculator, the user-defined default value of a corresponding parameter, wherein the graphical expression calculator includes the calculated default value of the expression, which is updated as the expression displayed in the expression field is edited.

12. The computer system of claim 9, wherein the recorded scenario comprises the user-defined default value of each parameter of the user-defined parameter set.

13. The computer system of claim 9, wherein the one or more agents are rendered in the image based on:
the user-defined default value of a parameter assigned to an agent field, and/or
a default value of an expression assigned to an agent field, as calculated based on the user-defined default value(s) of the one or more parameters of the expression.

14. The computer system of claim 1, wherein the at least one processor is configured to create, responsive to user input for marking one or more locations in the image, the one or agents in the image of the environment.

15. The computer system of claim 1, wherein the parameter generator is configured to associate each parameter with a user-defined range responsive to user input defining the user-defined range of the parameter, wherein the recorded scenario comprises the user-defined range of each parameter of the user-defined parameter set.

16. The computer system of claim 1 for testing performance of a robotic system in simulation, the computer system comprising:
a simulator configured to run one or more instances of the scenario in a simulation environment with the robotic system in control of an ego agent of the scenario;
a test oracle configured to process each instance of the test scenario and provide one or more outputs for assessing the performance of the robotic system therein; and
a test orchestration component, wherein the user-defined parameter set of the scenario is exposed to the test orchestration component and the test orchestration component is configured to assign a value to each parameter of the user-defined parameter set for each instance of the scenario, wherein the user-defined expression set is not exposed to the test orchestration component and the simulator is configured to compute each expression based on the value(s) assigned to its one or more parameters by the test orchestration component.

17. The computer system of claim 16, wherein the parameter generator is configured to associate each parameter with a user-defined range responsive to user input defining the user-defined range of the parameter, wherein the recorded scenario comprises the user-defined range of each parameter of the user-defined parameter set; and
wherein the test orchestration component is configured to sample the value of each parameter from its user-defined range.

18. At least one non-transitory computer readable medium embodying computer program instructions, the computer program instructions configured so as, when executed on one or more hardware processors, to implement operations for generating a scenario to be run in a simulation environment for testing behaviour of an autonomous vehicle, the operations comprising:
generating display data for causing a display to render a graphical user interface comprising an image of a driving environment and one or more agents within the driving environment;
generating in memory a user-defined parameter set responsive to user input defining the parameter set;
storing in memory a user-defined expression set, responsive to user input defining the expression set, wherein each expression of the expression set is a user-defined function of one or more parameters of the parameter set; and
recording a scenario in a scenario database;
wherein the graphical user interface is configured to provide multiple agent fields for controlling the behaviour of the one or more agents when the scenario is run in a simulation environment, wherein each agent field is modifiable to associate therewith either a parameter of the user-defined parameter set or an expression of the user-defined expression set; and
wherein the recorded scenario comprises the driving environment, the one or more agents, the user-defined parameter set, the user-defined expression set, and any user-defined associations between (i) the multiple agent fields and the user-defined parameter set and (ii) the multiple agent fields and the user-defined expression set, wherein each parameter associated with an agent field is controllable to directly modify an agent behaviour, and each parameter that is included in expression associated with an agent field is controllable to indirectly modify an agent behaviour.

19. A computer implemented method for generating a scenario to be run in a simulation environment for testing behaviour of an autonomous vehicle, the method comprising:
generating display data for causing a display to render a graphical user interface comprising an image of a driving environment and one or more agents within the driving environment;
generating in memory a user-defined parameter set responsive to user input defining the parameter set;
storing in memory a user-defined expression set, responsive to user input defining the expression set, wherein each expression of the expression set is a user-defined function of one or more parameters of the parameter set; and
recording the scenario in a scenario database;
wherein the graphical user interface is configured to provide multiple agent fields for controlling the behaviour of the one or more agents when the scenario is run in a simulation environment, wherein each agent field is modifiable to associate therewith either a parameter of the user-defined parameter set or an expression of the user-defined expression set; and
wherein the recorded scenario comprises the driving environment, the one or more agents, the user-defined parameter set, the user-defined expression set, and any user-defined associations between (i) the multiple agent fields and the user-defined parameter set and (ii) the multiple agent fields and the user-defined expression set, wherein each parameter associated with an agent field is controllable to directly modify an agent behaviour, and each parameter that is included in expression associated with an agent field is controllable to indirectly modify an agent behaviour.

20. The method of claim 19, wherein the graphical user interface comprises a graphical expression calculator having an expression field for displaying an editable expression, wherein the expression is editable by providing user input denoting an expression element to be inserted in the expression.
